(19) United States
(12) Patent Application Publication
(10) Pub. No.: US 2026/0231377 A1
(43) Pub. Date: Aug. 6, 2026

(54) METHOD OF SELECTIVELY ENHANCING THE COOLING OF COMPONENTS OF A SERVER THROUGH VARIABLE AIRFLOW IMPEDANCE

(71) Applicant: Lenovo Global Technology (United States) Inc., Morrisville, NC (US)

(72) Inventors: Shreekanth Murthy Muthigi, Karnataka (IN); Jen-Hao Wu, Taipei (TW); Yu Chia Cheng, Taipei (TW)

(21) Appl. No.: 19/046,389

(22) Filed: Feb. 5, 2025

(51) Int. Cl. H05K 7/20; G06F 1/20

(52) U.S. Cl. CPC H05K 7/20836; G06F 1/206; H05K 7/20145; H05K 7/20727

(57) ABSTRACT

A method for selectively enhancing the cooling of components of a server through variable airflow impedance includes determining, by use of a processor, that a first component of a server can benefit from increased airflow compared to a second component that is adjacent to the first component and moving, by use of the processor, a screen in an airflow to the second component, where the screen is moved into a position in which an increased surface area thereof is within the airflow to the second component. The airflow to the second component and an airflow to the first component is provided by one or more fans directing the airflow toward the second component and the first component, respectively, and moving the screen into the airflow to the second component increases a volumetric flow rate of the airflow to the first component.

### FIELD

The subject matter disclosed herein relates to server cooling and more particularly relates to selectively enhancing the cooling of components of a server through variable airflow impedance.

### BACKGROUND

Normally airflow impedance of a central processing unit (“CPU”) heatsink and dual inline memory module (“DIMM”) area is determined by their geometry, size, pitch, position inside chassis. The airflow to DIMMs and CPU is fixed for a given fan speed and the supported CPU power and DIMM power is predetermined and it cannot be changed. However if a variation of DIMM power or CPU power is needed, changing of cooling is not possible in such a configuration.

### BRIEF SUMMARY

A method for selectively enhancing the cooling of components of a server through variable airflow impedance includes determining, by use of a processor, that a first component of a server can benefit from increased airflow compared to a second component that is adjacent to the first component, and moving, by use of the processor, a screen in an airflow to the second component, where the screen is moved into a position in which an increased surface area thereof is within the airflow to the second component. The airflow to the second component and an airflow to the first component is provided by one or more fans directing the airflow toward the second component and the first component, respectively, and moving the screen into the airflow to the second component increases a volumetric flow rate of the airflow to the first component.

An apparatus for selectively enhancing the cooling of components of a server through variable airflow impedance includes a processor and non-transitory computer readable storage media storing code. The code is executable by the processor to perform operations that include determining that a first component of a server can benefit from increased airflow compared to a second component that is adjacent to the first component and moving a screen in an airflow to the second component, where the screen is moved into a position in which an increased surface area thereof is within the airflow to the second component. The airflow to the second component and an airflow to the first component are provided by one or more fans directing the airflow toward the second component and the first component, respectively, and moving the screen into the airflow to the second component increases a volumetric flow rate of the airflow to the first component.

A computing device for selectively enhancing the cooling of components of a server through variable airflow impedance includes one or more fans, a processor, a plurality of memory cards, and non-transitory computer readable storage media storing code. The code is executable by the processor to perform operations that include determining that the processor can benefit from increased airflow compared to the plurality of memory cards that are adjacent to the processor, and moving, by use of the processor, one or more screens in an airflow to the plurality of memory cards, where the one or more screens are moved into a position in which an increased surface area thereof is within airflow to the plurality of memory cards. The airflow is provided by the one or more fans directing airflow toward the processor and the plurality of memory cards, and moving the one or more screens into the airflow to the plurality of memory cards increases a volumetric flow rate of the airflow to the processor.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1 is a perspective view of a schematic block diagram illustrating a server with movable screens in the airflow ahead of first components in the form of processors and second components in the form of memory cards, according to various embodiments;

FIG. 2 is a schematic block diagram illustrating a dual server with movable screens in the airflow ahead of first components in the form of processors and second components in the form of memory cards, according to various embodiments;

FIG. 3 is a schematic block diagram illustrating a section view illustrating the movable screens of FIG. 2, according to various embodiments;

FIG. 4A is a schematic block diagram illustrating a movable screen with zero percent of the screen moved down, according to various embodiments;

FIG. 4B is a schematic block diagram illustrating the movable screen of FIG. 4A with fifty percent of the screen moved down, according to various embodiments;

FIG. 4C is a schematic block diagram illustrating the movable screen of FIG. 4A with one hundred percent of the screen moved down, according to various embodiments;

FIG. 5A is a schematic block diagram illustrating three movable screens in the airflow to a first component and a plurality of second components where the screens are in tracks, according to various embodiments;

FIG. 5B is a schematic block diagram illustrating a section view of the three movable screens of FIG. 5A illustrating the screens in the tracks, according to various embodiments;

FIG. 5C is a schematic block diagram illustrating a detailed section view of a track, according to various embodiments;

FIG. 6 is a schematic block diagram side view of a motor connected to a cable connected to a movable screen, according to various embodiments;

FIG. 7 is a schematic block diagram illustrating a slotted screen, according to various embodiments;

FIG. 8 is a schematic flow chart diagram illustrating a method for controlling screens in airflow to first and second components, according to various embodiments; and

FIG. 9 is a schematic flow chart diagram illustrating another method for controlling screens in airflow to first and second components, according to various embodiments.

### DETAILED DESCRIPTION

As will be appreciated by one skilled in the art, aspects of the embodiments may be embodied as a system, method or program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a program product embodied in one or more computer readable storage devices storing machine readable code, computer readable code, and/or program code, referred hereafter as code. The storage devices, in some embodiments, are tangible, non-transitory, and/or non-transmission.

Many of the functional units described in this specification have been labeled as modules, in order to more particularly emphasize their implementation independence. For example, a module may be implemented as a hardware circuit comprising custom very large scale integrated (“VLSI”) circuits or gate arrays, off-the-shelf semiconductors such as logic chips, transistors, or other discrete components. A module may also be implemented in programmable hardware devices such as a field programmable gate array (“FPGA”), programmable array logic, programmable logic devices or the like.

Modules may also be implemented in code and/or software for execution by various types of processors. An identified module of code may, for instance, comprise one or more physical or logical blocks of executable code which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different computer readable storage devices. Where a module or portions of a module are implemented in software, the software portions are stored on one or more computer readable storage devices.

Any combination of one or more computer readable medium may be utilized. The computer readable medium may be a computer readable storage medium. The computer readable storage medium may be a storage device storing the code. The storage device may be, for example, but not limited to, an electronic, magnetic, optical, electromagnetic, infrared, holographic, micromechanical, or semiconductor system, apparatus, or device, or any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

More specific examples (a non-exhaustive list) of the storage device would include the following: an electrical connection having one or more wires, a portable computer diskette, a hard disk, a random access memory (“RAM”), a read-only memory (“ROM”), an erasable programmable read-only memory (“EPROM” or Flash memory), a portable compact disc read-only memory (“CD-ROM”), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Code for carrying out operations for embodiments may be written in any combination of one or more programming languages including an object oriented programming language such as Python, Ruby, R, Java, Java Script, Smalltalk, C++, C sharp, Lisp, Clojure, PHP, or the like, and conventional procedural programming languages, such as the “C” programming language, or the like, and/or machine languages such as assembly languages. The code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (“LAN”) or a wide area network (“WAN”), or the connection may be made to an external computer (for example, through the Internet using an Internet Service Provider).

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatuses, systems, and program products according to embodiments. It will be understood that each block of the schematic flowchart diagrams and/or schematic block diagrams, and combinations of blocks in the schematic flowchart diagrams and/or schematic block diagrams, can be implemented by code. This code may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

The code may also be stored in a storage device that can direct a computer, other programmable data processing apparatus, or other devices to function in a particular manner, such that the instructions stored in the storage device produce an article of manufacture including instructions which implement the function/act specified in the schematic flowchart diagrams and/or schematic block diagrams block or blocks.

The code may also be loaded onto a computer, other programmable data processing apparatus, or other devices to cause a series of operational steps to be performed on the computer, other programmable apparatus or other devices to produce a computer implemented process such that the code which execute on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and program products according to various embodiments. In this regard, each block in the schematic flowchart diagrams and/or schematic block diagrams may represent a module, segment, or portion of code, which comprises one or more executable instructions of the code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and code.

The description of elements in each figure may refer to elements of proceeding figures. Like numbers refer to like elements in all figures, including alternate embodiments of like elements.

As used herein, a list with a conjunction of “and/or” includes any single item in the list or a combination of items in the list. For example, a list of A, B and/or C includes only A, only B, only C, a combination of A and B, a combination of B and C, a combination of A and C or a combination of A, B and C. As used herein, a list using the terminology “one or more of” includes any single item in the list or a combination of items in the list. For example, one or more of A, B and C includes only A, only B, only C, a combination of A and B, a combination of B and C, a combination of A and C or a combination of A, B and C. As used herein, a list using the terminology “one of” includes one and only one of any single item in the list. For example, “one of A, B and C” includes only A, only B or only C and excludes combinations of A, B and C.

A method for selectively enhancing the cooling of components of a server through variable airflow impedance includes determining, by use of a processor, that a first component of a server can benefit from increased airflow compared to a second component that is adjacent to the first component and moving, by use of the processor, a screen in an airflow to the second component where the screen is moved into a position in which an increased surface area thereof is within the airflow to the second component. The airflow to the second component and an airflow to the first component are provided by one or more fans directing the airflow toward the second component and the first component, respectively, and moving the screen into the airflow to the second component increases a volumetric flow rate of the airflow to the first component.

In some embodiments, the screen in the airflow of the second component is aligned with a screen in the airflow to the first component in a direction that is transverse to an airflow direction of the airflow to the first component and an airflow direction of the airflow to the second component. In other embodiments, one of the first component and the second component includes a processor and the other of the second component and the first component includes a memory card. In other embodiments, determining that the first component can benefit from the increased airflow includes determining at a second point in time that a temperature of the first component has increased relative to a first point in time. In other embodiments, determining that the first component can benefit from the increased airflow comprises determining that a rate of temperature change of the first component over a period of time exceeds a predetermined threshold. In other embodiments, the processor is coupled to a plurality of temperature sensors, a controller, and motors to raise and lower the screens in the airflows to the first and second components.

In some embodiments, determining that the first component can benefit from the increased airflow includes determining that an upcoming workload to be processed by the server will cause an increase in power consumption by the first component that is greater than a change in power consumption by the second component. In other embodiments, the method includes determining, by use of the processor, that the second component can benefit from increased air flow, moving, by use of the processor, all or a portion of the screen in the airflow to the second component, to a position out of the airflow to the second component, and moving, by use of the processor, all or a portion of the screen in airflow to the first component, to a position within the airflow to the first component.

In some embodiments, the screens in the airflow to the first component and the screens in the airflow to the second component include one or more of a motorized rod upon which the screens are wound, and a motorized pully system connected to the screens. In other embodiments, each of the screens in the airflow to the first component and the airflow to the second component include a track guiding an edge of the screens. In other embodiments, the screens in the airflow to the first components and in the airflow to the second component allow, in extended positions, a volumetric flow rate of air through the screens less than a volumetric flow rate of air with the screens in retracted positions. In some embodiments, a cooler is connected to a rod upon which a screen is wound, and the cooler is thermally coupled to the rod to cool the rod and the rod is thermally coupled to the screen to cool the screen. In other embodiments, the screen in the airflow to the second component includes a vertical slot positioned ahead of a hotspot of the second component and/or the screen in the airflow to the first component includes a vertical slot positioned ahead of a hotspot of the first component.

An apparatus for selectively enhancing the cooling of components of a server through variable airflow impedance includes a processor and non-transitory computer readable storage media storing code where the code is executable by the processor to perform operations that include determining that a first component of a server can benefit from increased airflow compared to a second component that is adjacent to the first component and moving a screen in an airflow to the second component, where the screen is moved into a position in which an increased surface area thereof is within the airflow to the second component. The airflow to the second component and an airflow to the first component are provided by one or more fans directing the airflow toward the second component and the first component, respectively, and moving the screen into the airflow to the second component increases a volumetric flow rate of the airflow to the first component.

In some embodiments, one of the first component and the second component includes a processor and the other of the second component includes a memory card. In other embodiments, determining that the first component can benefit from the increased airflow includes determining at a second point in time that a temperature of first component has increased relative to a first point in time. In other embodiments, determining that the first component can benefit from the increased airflow includes determining that a rate of temperature change of the first component over a period of time exceeds a predetermined threshold.

In some embodiments, the operations include determining, by use of the processor, that the second component can benefit from increased air flow, moving, by use of the processor, all or a portion of the screen in the airflow to the second component, to a position out of the airflow to the second component, and moving, by use of the processor, all or a portion of the screen in airflow to the first component, to a position within the airflow to the first component. In other embodiments, the screens of the first component and the second component include one or more of a motorized rod upon which the screens are wound, and a motorized pully system connected to a screen of the screens in the airflow to the first and second components. In other embodiments, the screens of the first component and the second component include a track guiding an edge of the one or more screens.

A computing device for selectively enhancing the cooling of components of a server through variable airflow impedance includes one or more fans, a processor, a plurality of memory cards, and non-transitory computer readable storage media storing code. The code is executable by the processor to perform operations that include determining that the processor can benefit from increased airflow compared to the plurality of memory cards that are adjacent to the processor, and moving, by use of the processor, one or more screens in an airflow to the plurality of memory cards, where the one or more screens are moved into a position in which an increased surface area thereof is within airflow to the plurality of memory cards. The airflow is provided by the one or more fans directing airflow toward the processor and the plurality of memory cards, and moving the one or more screens into the airflow to the plurality of memory cards increases a volumetric flow rate of the airflow to the processor.

In some embodiments, the operations include determining, by use of the processor, that one or more of the plurality of memory cards can benefit from increased air flow, moving, by use of the processor, all or a portion of the one or more screens in the airflow to the plurality of memory cards, to a position out of the airflow to the plurality of memory cards, and moving, by use of the processor, all or a portion of the screen in airflow to the processor, to a position within the airflow to the processor.

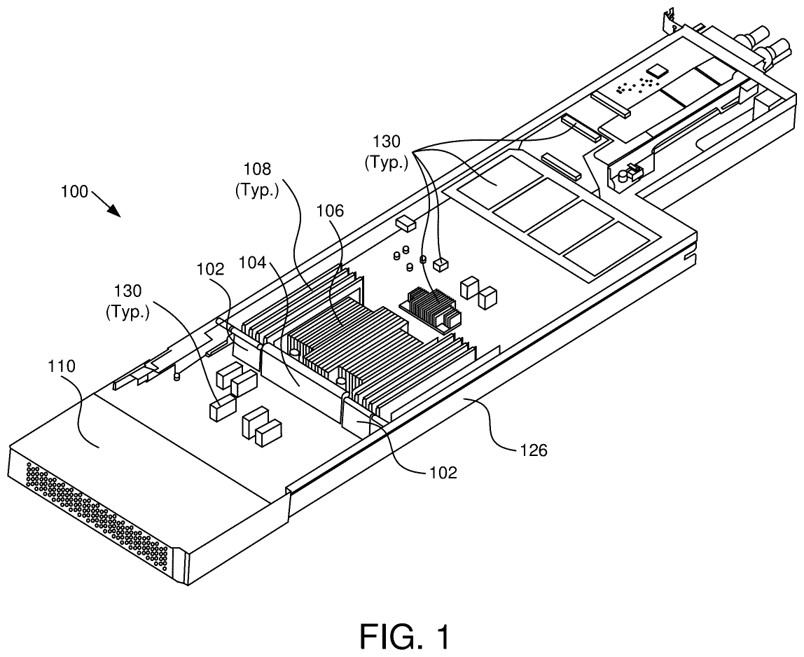

FIG. 1 is a perspective view of a schematic block diagram illustrating a server 100 with movable screens 102, 104 in the airflow ahead of first components in the form of processors 106 and second components in the form of memory cards 108, according to various embodiments. The server 100 includes one or more fans 110 that provide airflow towards the processors 106 and memory cards 108 and other components 130 of the server 100. While the fans 110 are depicted ahead of the processors 106 and memory cards 108, in other embodiments the fans 110 are located behind the processors 106 and memory cards 108 and draw the airflow running across the processors 106 and memory cards 108 before the airflow reaches the fans 110. The server 100 is enclosed in a chassis 126. A chassis cover (not shown for clarity) covers the server 100 so that airflow from the fans 110 is directed through the chassis 126. In some embodiments, the screens 102, 104 are mounted to the chassis cover. In other embodiments, the screens 102, 104 are mounted elsewhere. In some examples, the screens 102, 104 are mounted to a rod extending across the chassis 126 or brackets extending from the motherboard of the server 100. The screens 102, 104 are depicted in a fully down condition to depict where the screens 102, 104 are located. In typical operation, some screens (e.g., 102) may be partially or fully down while other screens (e.g., 104) are fully retracted, or vice-versa.

In some embodiments, the movable screens 102 for the memory cards 108 are positioned in the airflow from the fans 110 ahead of the memory cards 108. Likewise, in some embodiments the screens 104 for the processors 106 are positioned in the airflow from the fans 110 of the processors 106. In some embodiments, the screens 102, 104 are positioned to be rolled up out of the airflow to the processors 106 and memory cards 108. When the processors 106 could benefit from more airflow, in some embodiments, the screens 102 in front of the memory cards 108 are moved down either partially or fully and the screen 104 for the processors 106 is retracted partially or fully out of the airflow to the processors 106. In other embodiments, when the memory cards 108 could benefit from more airflow, the screen 104 for the processors 106 are moved partially or fully into the airflow to the processors 106 and the screens 102 for the memory cards 108 are retracted partially or fully out of the airflow to the memory cards 108.

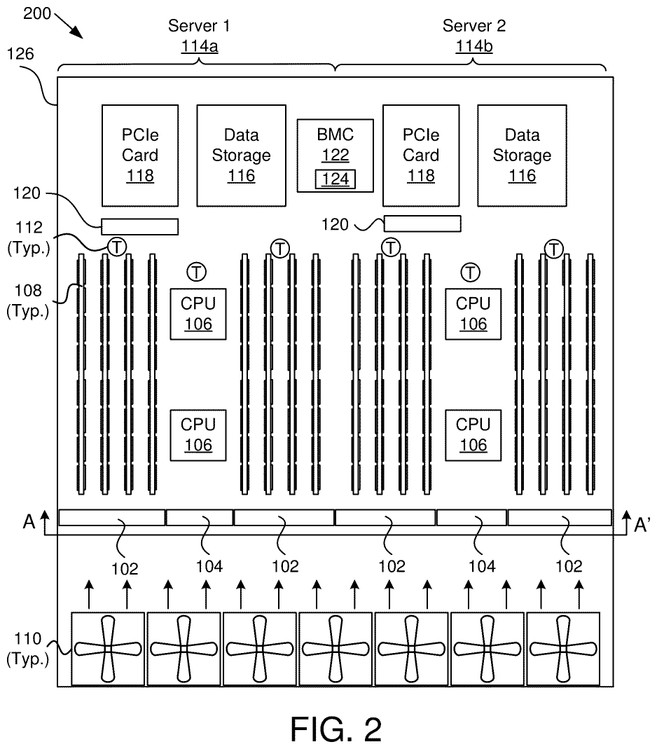

FIG. 2 is a schematic block diagram illustrating a plan view of a dual server 200 with movable screens 102, 104 in the airflow ahead of first components in the form of processors (each labeled central processing unit (“CPU”) 106) and second components in the form of memory cards 108, according to various embodiments. In the embodiments, the screens 102, 104 are aligned in a direction that is transverse to an airflow direction of the airflow to the first component and an airflow direction of the airflow to the second component. In other embodiments, the screens 102, 104 are not aligned. In the embodiments, the screens 102, 104 may have other materials that block airflow between the screens 102, 104. In some embodiments, the screens 102 on the ends include materials to block airflow around the ends. The dual server 200 includes a first server 114a and a second server 114b that are positioned next to each other. The dual server 200 also includes data storage 116, which may be non-volatile memory, hard disk drives (“HDDs”), or the like. The dual server 200 also includes peripheral component interconnect express (“PCIe”) cards 118. In some embodiments, additional screens 120 are in the airflow to other components, such as the PCIe cards 118.

Temperature sensors 112, in some embodiments, are included in the dual server 200 and provide temperature feedback to a screen apparatus 124 depicted in a baseboard management controller (“BMC”) 122, which controls motors for the screens 102, 104, 120. In other embodiments, the screen apparatus 124 is located elsewhere, such as in a CPU 106, in a basic input/output system (“BIOS”), unified extensible firmware interface (“UEFI”), or the like.

A BMC 122 is used to control the dual server 200 remotely. Typically, the BMC 122 is connected to a management network that is typically separate from a data network used by the dual server 200. In some embodiments, the BMC 122 monitors physical conditional of the dual server 200, such as temperature, fan speed, and the like. In some embodiments, the BMC 122 is able to update software of the dual server 200 via a remote connection. Where the dual server 200 is located in a datacenter, a group of servers each include a BMC 122, which are connected over the management network with a management server on premises, which is connected to a remote management server used to control the servers of the datacenter. In other embodiments, the BMC 122 is connected remotely to a management server, for examples, where the servers are in an edge server environment.

The BMC 122 is an XClarity® Controller (“XCC”) by Lenovo®. In other embodiments, the BMC 122 is Management Engine (“ME”) by Intel®. In other embodiments, the BMC 122 is another type by another manufacturer. In general, a BMC 122 in an edge computing device may be a controller used to monitor and manage the edge computing device remotely. The BMC may be, for example, used for health monitoring, power management, firmware management, event logging, security, etc. In some embodiments, the management server is an XClarity Administrator (“XCA”) by Lenovo. In various embodiments, the remote management server is an XCA or an XClarity Orchestrator (“XCO”) by Lenovo.

The screen apparatus 124, in some embodiments, is connected to the temperature sensors 112, which provide temperature information from within the dual server 200. In other embodiments, the screen apparatus 124 receives temperature information from the BMC 122, which received temperature information from the temperature sensors 112. In some embodiments, the screen apparatus 124 is connected to the screens 102, 104, 120 and is able to raise and lower the screens 102, 104, 120 fully or partially based on the temperature data. In other embodiments, the screen apparatus 124 is configured to raise and lower the screens 102, 104, 120 based on commands from the BMC 122, which may originate in the BMC 122 or be received by the BMC 122.

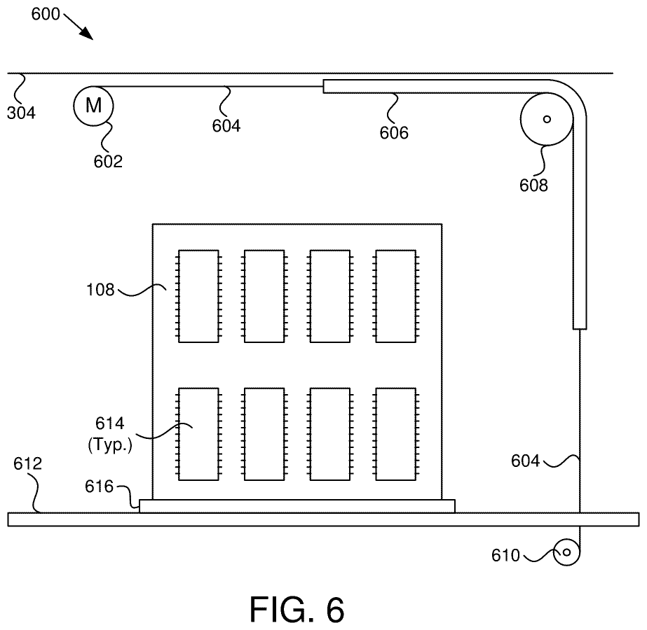

In some embodiments, the temperature sensors 112 provide temperature information to a user, such as a system administrator, which in turn raises or lowers the screens 102, 104, 120 manually. In some embodiments, the user sends commands manually, such as through the BMC 122, to raise and the lower screens 102, 104, 120. In other embodiments, the screens 102, 104, 120 each have a mechanism to manually raise and lower the screens 102, 104, 120. In some examples, the screens are mounted to a chassis cover and have a wheel that is connected to each screen and the user turns a wheel of a screen (e.g., 102) to raise or lower that screen 102. In some embodiments, the wheel extends through a slot on the chassis cover or chassis 126. In other embodiments, one or more of the screens 102, 104, 120 move vertically to a roller, such as the roller 608 in FIG. 6, and past the roller the screens 102, 104, 120 move horizontally. In the embodiments, the screens 102, 104, 120 have a tab that extends through a slot in the chassis cover or chassis 126 and the user moves the tab to move the screen 102, 104, 120. In other embodiments, the user removes the chassis cover to move the screens 102, 104, 120.

In some embodiments, the screen apparatus 124 determines that a first component of a server 114a, 114b, such as the CPUs 106, can benefit from increased airflow compared to a second component, such as the memory cards 108, that are adjacent to the first component. The screen apparatus 124 moves a screen 102 in an airflow to the second components (the memory cards 108) where the screen 102 is moved into a position in which an increased surface area thereof is within the airflow to the second component (the memory cards 108) to partially obstruct the airflow to the memory cards 108. In some embodiments where there are to banks of memory cards 108 in the form of dual inline memory modules (“DIMMs”), the screens 102 for the DIMMs 108 are controlled separately. In other embodiments, where there are to banks of DIMMs 108, the screens 102 for the DIMMs 108 are controlled together. In some embodiments, determining that the CPUs 106 can benefit from the increased airflow includes determining that a temperature of the CPUs 106 has increased.

In other embodiments, determining that the temperature of the first component (CPUs 106) has increased includes using temperature data from a temperature sensor 112 within the dual server 200 that is part of a feedback loop that raises and lowers the screens 102, 104, 120 for the first component (CPUs 106), the screen for second components (memory cards 108) and/or other component, such as the PCIe card 118. In some embodiments, the feedback loop includes a plurality of temperature sensors 112, a controller (screen apparatus 124), and motors to raise and lower the screen 102, 104, 120 of the first and second components, or other device (PCIe card 118). In some embodiments, determining that the first component (CPU 106) can benefit from the increased airflow includes determining that an upcoming workload to be processed by the server 114a, 114b with cause an increase in power consumption by the first component (CPU 106) that is greater than a change in power consumption by the second component (memory cards 108). In other embodiments, movement of the screens 102, 104, 120 is by way of a pre-defined program that has rules of required opening versus temperatures of a particular component.

In some embodiments, determining that the first component can benefit from the increased airflow includes determining that a rate of temperature change of the first component over a period of time exceeds a predetermined threshold. In some embodiments, a system administrator sets the predetermined threshold.

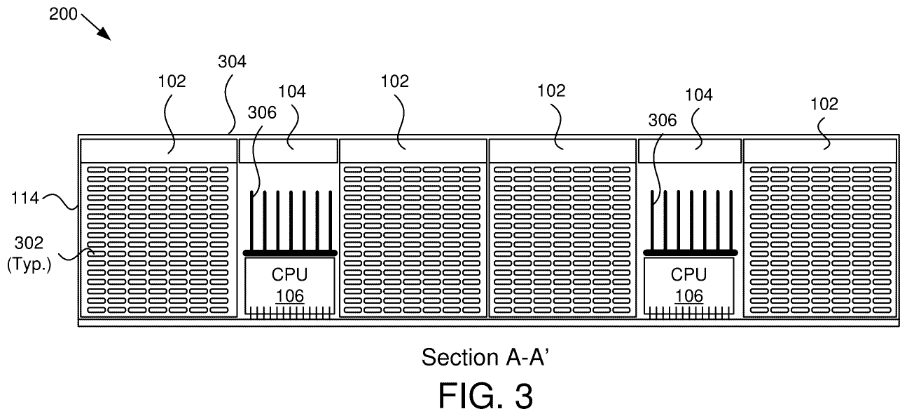

FIG. 3 is a schematic block diagram illustrating a section view illustrating the movable screens 102, 104 of FIG. 2, according to various embodiments. In the depicted embodiments of FIG. 3, the screens 104 of the processors 106 are raised while the screens 102 for the memory cards 108 are lowered. Note that the screens 102 have openings 302 to allow airflow through the screens 102. The chassis 126 is depicted along with a chassis cover 304. The CPUs 106 include a heat sink 306 above the CPUs 106. While the screens 102 are depicted as fully lowered, in other examples, the screens 102 may be partially lowered.

In some embodiments, the screens 102, 104, 120 are metal with openings 302 stamped into the metal. In other embodiments, the screens 102, 104, 120 are a chainmail or a chain link material with openings 302. In various embodiments, the screens 102, 104, 120 are a plastic, a composite, or other non-metallic material with openings 302 stamped into the screens 102, 104, 120, or without openings. In some embodiments, the screens 102, 104, 120 have openings with a perforation size, pitch, shape, etc. sized to provide a particular amount of airflow through the screen to achieve a desired temperature and/or supported power of the components behind the screens 102, 104, 120. In some embodiments, the material for the screens 102, 104, 120 are selected based on ability to retain a straightness when not rolled while being able to be rolled. In some embodiments, the material for the screens 102, 104, 120 is selected based on whether or not the screens 102, 104, 120 will have tracks, guides, etc. In some examples where the screens 102, 104, 120 do not have tracks, the material for the screens 102, 104, 120 is chosen to be stiff and straight when not rolled. One of skill in the art will recognize materials appropriate for the screens 102, 104, 120.

In some embodiments, the screens 102, 104, 120 may be used to compensate for failure of a fan 110. Where a fan 110 fails, the screens 102, 104, 120 may be adjusted in terms of opening and closing fully or partially to compensate for the fan failure. In some embodiments, the screen apparatus 124 senses temperature variations from the temperature sensors 112 and adjusts the opening and closing of the screens 102, 104, 120 accordingly. In other embodiments, a user adjusts the screens 102, 104, 120 manually, either mechanically or using the screen apparatus 124. In other embodiments, the screen apparatus 124 adjusts the screens 102, 104, 120 based on a preprogrammed plan based on the particular fan 110 that has failed.

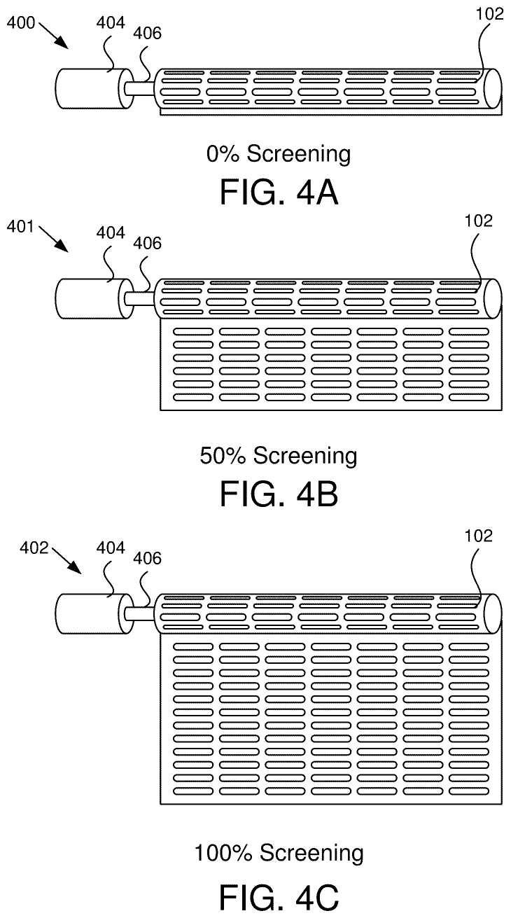

In some embodiments, one or more of the screens 102, 104, 120 are connected to a cooler, which could be part of the motor 404 in FIGS. 4A-C, that cools a rod 406 upon which the screens 102, 104, 120 are wound. In other embodiments, the cooler is incorporated elsewhere and connected to the rod 406. The cooler then cools the rod 406, which in turn cools the screens 102, 104, 120, which provides additional cooling for the servers 114a, 114b. In some embodiments, the cooler is a thermoelectric cooler or Peltier cooler. In other embodiments, the cooler includes a cooling loop connected to a heat exchanger, a compression valve/a compressor, to a pump, etc. In other embodiments, the cooler is a piezoelectric cooler.

FIG. 4A is a schematic block diagram 400 illustrating a movable screen 102 with zero percent of the screen 102 moved down, according to various embodiments. The screen 102 is driven by a motor 404 connected to a shaft 406. While the motor 404 is shown to the side of the screen 102, in other embodiments, the motor 404 is located elsewhere, such as within the rolled up screen 102. In other embodiments, the motor is connected to a gear and the screen 102 has a shaft 406 connected to a gear and a chain is connected between the gears. One of skill in the art will recognize other locations of the motor 404 that is capable of moving the screen 102.

The screen 102 is depicted in the fully retracted position. FIG. 4B is a schematic block diagram 401 illustrating the movable screen 102 of FIG. 4A with fifty percent of the screen 102 moved down, according to various embodiments. FIG. 4C is a schematic block diagram 402 illustrating the movable screen 102 of FIG. 4A with one hundred percent of the screen 102 moved down, according to various embodiments. Note that while the screens 102, 104, 120 depicted in FIGS. 1-3, 4A, 4B, 4C all are depicted as moving downward, in other embodiments, the screens 102, 104, 120 may move sideways, upwards, etc. In some embodiments, the screens 102, 104, 120 are in multiple parts where the various parts move from different directions into the airflow to the component where airflow is being reduced.

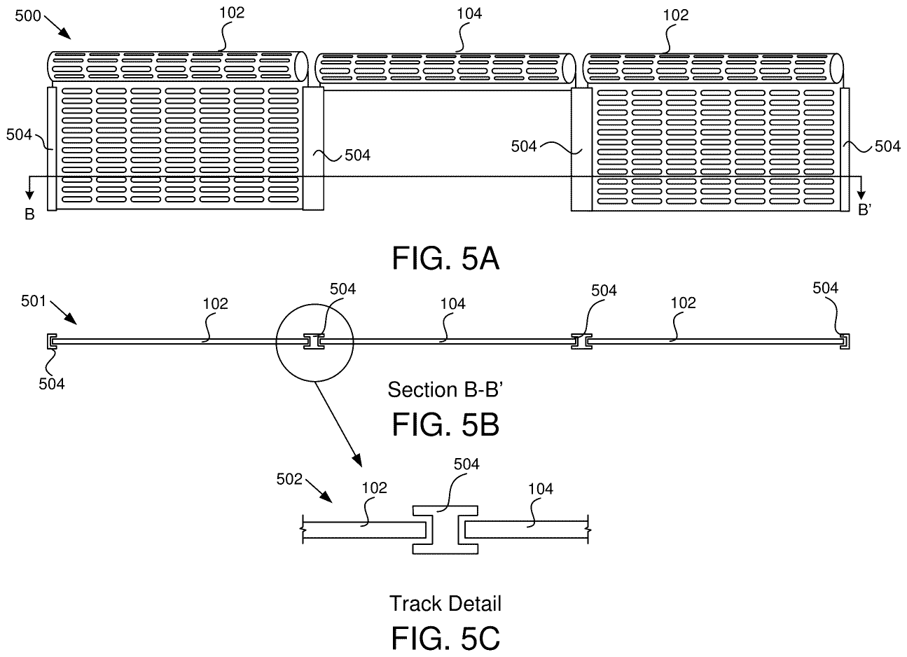

FIG. 5A is a schematic block diagram 500 illustrating three movable screens 102, 104 in the airflow to a first component (e.g. CPU 106) and a plurality of second components (e.g., memory cards 108) where the screens 102, 104 are in tracks 504, according to various embodiments. The tracks 504 are either a single track 504 for an end or a double track 504 between two screens 102, 104. The tracks 504 function to keep the screens 102, 104 moving up and down and the tracks 504 help to keep the screens 102, 104 from moving towards or away from the first or second components. In some examples, the screens 102, 104 are flexible enough to be moved by the airflow from the fans 110 and the tracks prevent unwanted horizontal movement. In some embodiments, there may be additional air blocking components on the ends of the screens 102, 104, above the screens 102, 104, etc. to force air to be channeled towards the components behind the screens 102, 104.

FIG. 5B is a schematic block diagram 501 illustrating a section view of the three movable screens 102, 104 of FIG. 5A illustrating the screens 102 in the tracks 504, according to various embodiments. FIG. 5C is a schematic block diagram 502 illustrating a detailed section view of the track 504, according to various embodiments. The tracks 504 include a groove sized to fit around the ends of the screens 102, 104. In some embodiments, the ends of the screens 102, 104 include a low resistance material to facilitate the screens 102, 104 moving easily in the tracks 504. In other embodiments, the tracks 504 include a low resistance material so that the screens 102, 104 move easily within the tracks 504. In other embodiments without tracks 504, some designs may include guides instead of tracks 504. The guides are positioned at strategic positions to guide the screens 102, 104, 120 without having tracks 504 running the full length of the screens 102, 104, 120.

FIG. 6 is a schematic block diagram side view 600 of a motor 602 connected to a cable 604 connected to a movable screen 606, according to various embodiments. In the embodiments of FIG. 6, the screen 606 is configured to move up to a roller 608 designed to allow the screen 606 to rotate to a horizonal movement, much like a garage door. The cable 604 is connected to the screen 606 and the motor 602 includes a reel where the cable is wound as the screen 606 moves up. In the depicted embodiments, the bottom edge of the screen 606 is also connected to a cable 604, which is connected to a take-up reel 610 configured to allow the cable 604 to unwind from the take-up reel 610 as the screen 606 moves upward and to rotate and wind up cable 604 as the screen 606 moves downward. In some embodiments, the take-up reel 610 is spring loaded so that the cable 604 automatically retracts into the take-up reel 610 as the screen 606 is lowered and keeps tension on the bottom of the screen 606. In other embodiments, the take-up reel 610 is replaced by a motor 602 and reel that work with the motor 602 and reel at the top. In other embodiments, the take-up reel 610 is replaced by a pulley and the cable 604 extends through one or more other pulleys back to the motor 602, where the cable 604 is wound or travels past a reel on the motor 602.

In the depicted embodiment, the screen 606 is positioned in the airflow to a memory card 108. The memory card 108 includes memory chips 614 and is plugged into a slot 616 within a motherboard 612. In the depicted embodiment, the take-up reel 610 is depicted below the motherboard 612. In other embodiments, the take-up reel 610 is located above the motherboard 612. The screen 606 is depicted next to a memory card 108, which includes memory chips 614 and is plugged into a slot 616. In other embodiments, the screen 606 is adjacent to another component, such as a CPU 106, a PCIe card 118, data storage 116, or other component. Note that the screen 606 is located just below a chassis cover 304. In other embodiments, the screen 606 is located lower. In such embodiments, an airflow blocker may be placed at the top of the screen 606 and may run to the chassis cover 304 to prevent airflow above the screen 606. In some embodiments, the screen 606 may replace the screens 102, 104, 120 depicted in FIGS. 1-3, 4A-C, 5A-C.

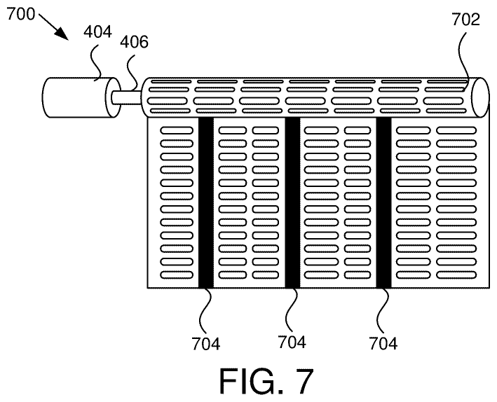

FIG. 7 is a schematic block diagram 700 illustrating a slotted screen 702, according to various embodiments. In some instances, the components downstream of the screen 702, such as memory cards 108 may have hotspots. In such cases, the screen 702 may include slots 704 in front of the hotspots to allow more airflow to the hotspots when the screen 702 is down.

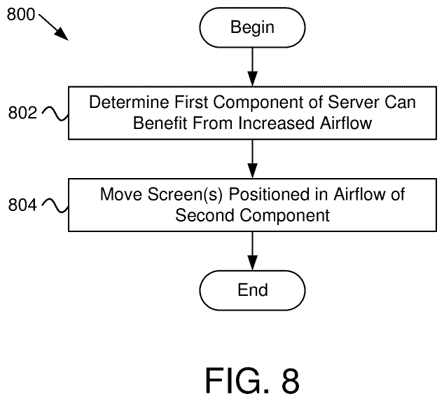

FIG. 8 is a schematic flow chart diagram illustrating a method 800 for controlling screens 102, 104, 120, 606 in airflow to first and second components, according to various embodiments. The method 800 begins and determines 802, by use of a processor, that a first component of a server 100, 114a, 114b, 200 can benefit from increased airflow compared to a second component that is adjacent to the first component. The airflow is provided by one or more fans 110 directing airflow across the first and second components. Moving the screen 104 into the airflow to the first component and/or moving the screen 102 into the airflow to the second component impedes the airflow from the one or more fans 110. Stated differently, moving the screen 104 into the airflow to the first component increases the airflow, volumetric flow rate of air, and/or mass flow rate of air exiting the one or more fans 110 and travelling toward the second component, and correspondingly decreases the airflow, volumetric flow rate of air, and/or mass flow rate of air exiting the one or more fans 110 and travelling toward the first component. Similarly, moving the screen 102 into the airflow to the second component increases the airflow, volumetric flow rate of air, and/or mass flow rate of air exiting the one or more fans 110 and travelling toward the first component, and correspondingly decreases the airflow, volumetric flow rate of air, and/or mass flow rate of air exiting the one or more fans 110 and travelling toward the second component. The method 800 moves 804, by use of the processor, a screen 102 in an airflow to the second components, and the method 800 ends. The screen 102 moves into airflow to the second component. In various embodiments, the method 800 is implemented using the screen apparatus 124.

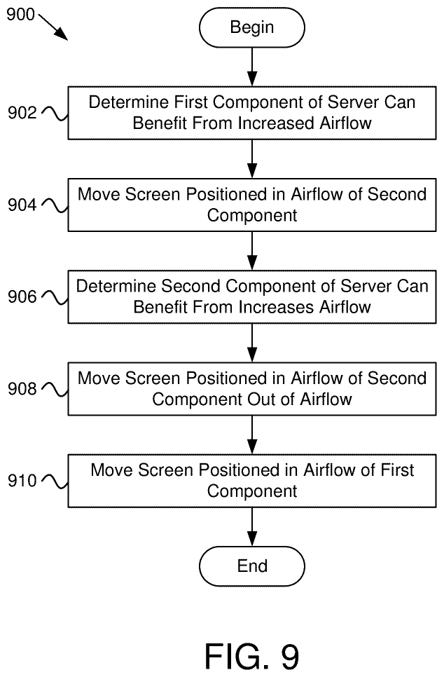

FIG. 9 is a schematic flow chart diagram illustrating another method 900 for controlling screens 102, 104 in airflow to first and second components, according to various embodiments. The method 900 begins and determines 902, by use of a processor, that a first component of a server 100, 114a, 114b, 200 can benefit from increased airflow compared to a second component that is adjacent to the first component. The airflow is provided by one or more fans 110 directing airflow across the first and second components. Moving the screen 104 into the airflow to the first component and moving the screen 102 into the airflow to the second component impedes the airflow from the one or more fans 110. The method 900 moves 904, by use of the processor, a screen 102 in an airflow to the second components where the screen 102 moves into airflow to the second component.

The method 900 determines 906, by use of the processor, that the second component can benefit from increased air flow and moves 908, by use of the processor, the screen 102 in the airflow to the second component, to a position out of the airflow to the second component. The method 900 moves 910, by use of the processor, the screen 104 in airflow to the first component, to a position within the airflow to the first component, and the method 900 ends. In various embodiments, the method 900 is implemented using the screen apparatus 124.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method comprising:
determining, by use of a processor, that a first component of a server can benefit from increased airflow compared to a second component that is adjacent to the first component; and
moving, by use of the processor, a screen in an airflow to the second component, the screen moved into a position in which an increased surface area thereof is within the airflow to the second component,
wherein the airflow to the second component and an airflow to the first component are provided by one or more fans directing the airflow toward the second component and the first component, respectively, and
wherein moving the screen into the airflow to the second component increases a volumetric flow rate of the airflow to the first component.

2. The method of claim 1, wherein the screen in the airflow to the second component is aligned with a screen in the airflow to the first component in a direction that is transverse to an airflow direction of the airflow to the first component and an airflow direction of the airflow to the second component.

3. The method of claim 1, wherein one of the first component and the second component comprises a processor and wherein the other of the second component and the first component comprises a memory card.

4. The method of claim 1, wherein determining that the first component can benefit from the increased airflow comprises determining at a second point in time that a temperature of the first component has increased relative to a first point in time.

5. The method of claim 1, wherein determining that the first component can benefit from the increased airflow comprises determining that a rate of temperature change of the first component over a period of time exceeds a predetermined threshold.

6. The method of claim 1, wherein the processor is coupled to a plurality of temperature sensors, a controller, and motors to raise and lower the screens in the airflows to the first and second components.

7. The method of claim 1, wherein determining that the first component can benefit from the increased airflow comprises determining that an upcoming workload to be processed by the server will cause an increase in power consumption by the first component that is greater than a change in power consumption by the second component.

8. The method of claim 1, further comprising:
determining, by use of the processor, that the second component can benefit from increased air flow;
moving, by use of the processor, all or a portion of the screen in the airflow to the second component, to a position out of the airflow to the second component; and
moving, by use of the processor, all or a portion of the screen in the airflow to the first component, to a position within the airflow to the first component.

9. The method of claim 1, wherein the screen in the airflow to the first component and the screen in the airflow to the second component comprise one or more of a motorized rod upon which the screens are wound, and a motorized pully system connected to the screens.

10. The method of claim 1, wherein each of the screens in the airflow to the first component and the airflow to the second component comprise a track guiding an edge of the screens.

11. The method of claim 1, wherein the screens in the airflow to the first components and the airflow to the second component allow, in extended positions, a volumetric flow rate of air through the screens less than a volumetric flow rate of air through the screens with the screens in retracted positions.

12. The method of claim 1, wherein a cooler is connected to a rod upon which a screen is wound, and wherein the cooler is thermally coupled to the rod to cool the rod and the rod is thermally coupled to the screen to cool the screen.

13. The method of claim 1, wherein the screen in the airflow to the second component comprises a vertical slot positioned ahead of a hotspot of the second component and/or the screen in the airflow to the first component comprises a vertical slot positioned ahead of a hotspot of the first component.

14. An apparatus comprising:
a processor; and
non-transitory computer readable storage media storing code, the code being executable by the processor to perform operations comprising:
determining that a first component of a server can benefit from increased airflow compared to a second component that is adjacent to the first component; and
moving a screen in an airflow to the second component, the screen moved into a position in which an increased surface area thereof is within the airflow to the second component,
wherein the airflow to the second component and an airflow to the first component are provided by one or more fans directing the airflow toward the second component and the first component, respectively, and
wherein moving the screen into the airflow to the second component increases a volumetric flow rate of the airflow to the first component.

15. The apparatus of claim 14, wherein one of the first component and the second component comprises a processor and the other of the second component and the first component comprises a memory card.

16. The apparatus of claim 14, wherein determining that the first component can benefit from the increased airflow comprises:
determining at a second point in time that a temperature of first component has increased relative to a first point in time; and
determining that a rate of temperature change of the first component over a period of time exceeds a predetermined threshold.

17. The apparatus of claim 14, wherein the operations further comprise:
determining, by use of the processor, that the second component can benefit from increased air flow;
moving, by use of the processor, all or a portion of the screen in the airflow to the second component, to a position out of the airflow to the second component; and
moving, by use of the processor, all or a portion of the screen in airflow to the first component, to a position within the airflow to the first component.

18. The apparatus of claim 14, wherein the screens of the first component and the second component comprise one or more of a motorized rod upon which the screens are wound, and a motorized pully system connected to a screen of the screens of the first and second components.

19. A computing device comprising:
one or more fans;
a processor;
a plurality of memory cards; and
non-transitory computer readable storage media storing code, the code being executable by the processor to perform operations comprising:
determining that the processor can benefit from increased airflow compared to the plurality of memory cards that are adjacent to the processor; and
moving, by use of the processor, one or more screens in an airflow to the plurality of memory cards, the one or more screens moved into a position in which an increased surface area thereof is within the airflow to the plurality of memory cards,
wherein the airflow is provided by the one or more fans directing airflow toward the processor and the plurality of memory cards, and
wherein moving the one or more screens into the airflow to the plurality of memory cards increases a volumetric flow rate of the airflow to the processor.

20. The computing device of claim 19, wherein the operations further comprise:
determining, by use of the processor, that one or more of the plurality of memory cards can benefit from increased air flow;
moving, by use of the processor, all or a portion of the one or more screens in the airflow to the plurality of memory cards, to a position out of the airflow to the plurality of memory cards; and
moving, by use of the processor, all or a portion of the screen positioned upstream in airflow to the processor, to a position within the airflow to the processor.
